(19) United States
(12) Patent Application Publication
(10) Pub. No.: US 2012/0112224 A1
(43) Pub. Date: May 10, 2012

(54) METHOD FOR PRODUCING A STRUCTURE WITH A TEXTURED EXTERNAL SURFACE, INTENDED FOR AN ORGANIC LIGHT EMITTING DIODE DEVICE, AND A STRUCTURE WITH A TEXTURED EXTERNAL SURFACE

(75) Inventors: David Le Bellac, Antibes (FR); Bernard Nghiem, Arsy (FR); François-Julien Vermersch, Paris (FR); Sophie Besson, Compiegne (FR)

(73) Assignee: Saint-Gobain Glass France, Courbevoie (FR)

(21) Appl. No.: 13/260,981

(22) PCT Filed: Apr. 2, 2010
(86) PCT No.: PCT/FR2010/050640

§ 371 Date: Jan. 23, 2012

(30) Foreign Application Priority Data
Apr. 2, 2009 (FR) 0952148

(51) Int. Cl. H01L 51/52; B32B 17/00; B32B 3/30; C03C 15/00; C03C 17/00

(52) U.S. Cl. 257/98; 65/31; 65/17.2; 428/141; 428/142; 216/41; 257/E51.018; 257/40

(57) ABSTRACT

A process for obtaining a structure having a textured external surface for an organic light-emitting device, which structure includes a mineral glass substrate having a surface which is provided with projections and depressions, the process including the deposition of an etching mask on the surface of the substrate and the etching of the surface of the substrate around the etching mask, and possible removal of the mask, wherein one of the steps of preparing the etching mask consists in forming a multitude of nodules randomly arranged on the surface of the substrate and made of a material possessing no affinity with the glass and wherein, after the etching step, the structure undergoes a moderating step in which the slopes of the projections of submicron height and width obtained by etching are moderated sufficiently to form the thus moderated textured external surface.

The invention relates to a process for producing a structure having a textured external surface for an organic light-emitting device, which structure comprises a mineral glass substrate, the surface of which is provided with projections and depressions, for an organic light-emitting diode device and to such a structure.

An organic light-emitting diode (OLED) device comprises an organic electroluminescent material or a stack of such materials, and is flanked by two electrodes, one of the electrodes, generally the anode, being that associated with the glass substrate and the other electrode, the cathode, being placed on the organic materials on the opposite side from the anode.

An OLED is a device that emits light by electroluminescence using recombination energy, i.e. the energy released when holes injected from the anode and electrons ejected from the cathode recombine. In the case when the cathode is not transparent, the emitted photons pass through the transparent anode and through the glass support substrate of the OLED so as to deliver light to the outside of the device.

The application of an OLED is generally in a display screen or more recently in an illumination device, with however different constraints.

For an illumination system, the light extracted from the OLED is “white” light emitting in certain, or even all, of the wavelengths of the visible spectrum. The light must also be homogenous. By this it is meant, more precisely, that the emission is Lambertian, that is to say it obeys Lambert's law by being characterized by a photometric luminescence equal in all directions.

Moreover, an OLED has a low light extraction efficiency: the ratio of the amount of light actually leaving the glass substrate to that emitted by the electroluminescent materials is relatively low, around 0.25.

This phenomenon is explained in particular by the fact that a certain number of photons remain trapped between the cathode and the anode.

It is therefore endeavored to find solutions for improving the efficiency of an OLED, namely to increase the extraction gain, while still providing white light which is as homogenous as possible. The term “homogenous” is understood in the rest of the description to mean both intensity and color homogeneity and homogeneity in space.

It is known to provide at the glass-anode interface a structure having periodic projections, constituting a diffraction grating and thus enabling the extraction gain to be increased.

Document US 2004/0227462 shows for this purpose an OLED having a textured transparent substrate for supporting the anode and the organic layer. The surface of the substrate thus has an alternation of projections and depressions, the profile of which is followed by the anode and the organic layer that are deposited thereon. The profile of the substrate is obtained by applying a photoresist mask on the surface of the substrate, the pattern of said mask corresponding to the desired pattern of the projections, and then by etching the surface through the mask.

However, such a process is not easy to carry out on an industrial scale over large substrate areas, and is above all too expensive, most particularly for illumination applications.

However, electrical deficiencies have been observed on OLEDs.

The invention therefore provides a method of producing a substrate, in particular for a polychromatic (white) OLED, providing simultaneously an increase in extraction, sufficiently homogenous white light and increased reliability.

According to the invention, the process for obtaining a structure having a textured external surface for an organic light-emitting device, which structure includes a mineral glass substrate having a surface which is provided with projections and depressions, comprises the deposition of an etching mask on the surface of the substrate and the etching of the surface of the substrate around the etching mask, and possible removal of the mask. One of the steps of preparing the etching mask consists in forming a multitude of nodules randomly arranged on the surface of the substrate and made of a material possessing no affinity with the glass and after the etching step, the structure undergoes a moderating step in which the slopes of the projections of submicron height and width obtained by etching are moderated sufficiently to form the thus moderated textured external surface.

By being periodic, the grating of the prior art does optimize the extraction gain around a certain wavelength, but on the other hand it is not conducive to the emission of white light. On the contrary, it tends to select certain wavelengths and for example emits more in the blue or in the red.

In contrast, the process according to the invention provides the substrate with a random external texture making it possible to obtain an extraction gain over a wide range of wavelengths (no visible colorimetric effect) and an almost Lambertian angular distribution of the emitted light.

Moreover, since overly pointed projections having excessively sharp angles risk causing electrical contact between the anode and the cathode, which would then degrade the OLED, the process according to the invention therefore incorporates a moderating step so as to control the surface finish.

To define the moderation of the surface, it may be preferable to introduce two roughness criteria whereby:
the well-known roughness parameter R_{dq}, indicating the mean slope, is set at a maximum value; and
the well-known roughness parameter Rₘₐₓ, indicating the maximum height, is set at a maximum value, possibly cumulative with a minimum value, in order to promote extraction.

Thus, in a preferred embodiment, the textured surface of the structure is defined by a roughness parameter R_{dq} of less than 1.5°, preferably less than 1° or even 0.7° or less, and a roughness parameter Rₘₐₓ of 100 nm or less, but preferably greater than 20 nm, over a 5 μm by 5 μm scanning area with for example 512 measurement points.

The scanning area is thus suitably chosen according to the roughness to be measured. The roughness parameters of the surface are thus preferably measured by atomic force microscopy (AFM).

Another method of defining the moderation of the external surface is to state that the angle made by the tangent to the normal to the substrate is equal to or greater than 30°, and preferably at least 45°, for most of the given points on this surface.

Preferably, for greater reliability of the OLED, at least 50%, or 70% and even 80% of that etching-textured face of the substrate to be covered with the active layer(s) of the OLED (to form one or more light-emitting zones) has an external surface with sufficiently moderated (typically rounded or wavy) submicron-scale texturing.

In other words, for a given number N of active light-emitting zones of an OLED, preferably at least 70% or even at least 80% of the N active zones has a moderated textured surface according to the invention.

For example, for production simplicity, the surface may be moderated substantially over the entire etched surface. Furthermore, the substrate may be textured by etching substantially over the entire main face involved.

To obtain the most representative possible analysis of the surface finish, a sufficient number of roughness measurements of the moderated external surface may of course be performed, in several sectors of the active zone(s) for the OLED. For example, measurements may be made at the center or around the periphery of possibly preselected active zones.

Another method other than measuring roughness for defining the moderation of the external surface is to state that the angle made by the tangent to the normal to the substrate is equal to or greater than 30°, and preferably at least 45°, for most of the given points on this surface.

It should be noted that document WO 02/02472 discloses a process for texturing a mineral glass substrate. This process consists in coating a planar substrate with a mask consisting of metal nodules and then in etching the substrate through the mask using a reactive plasma. The projections have heights of between 40 and 250 nm.

One example given in this document WO 02/02472 is to use a glass substrate provided with a coating of tin-doped indium oxide (ITO), to vacuum-deposit a layer of silver (Ag) on the substrate by magnetron sputtering and to carry out, under vacuum, a step of dewetting the Ag layer, which consists of a heat treatment (at a temperature of around 300° C.) so as to make only Ag nodules appear. The substrate then undergoes a reactive ion etching step in a plasma gas such as SF₆ and biasing the ITO layer with a radio frequency generator. Finally, that fraction of the mask remaining after the etching operation is removed, for example by immersing the etched substrate in an aqueous acid solution such as an HNO₃ solution.

Such a process by itself cannot be envisaged for obtaining a textured substrate intended for forming the support for an OLED, since the substrate obtained cannot meet the dimensional requirements for the texturing of a substrate for an OLED, since, as already indicated, the projections are too sharp.

According to the invention, the expression “material having no affinity with the glass” is understood to mean a material having a low energy of adhesion to the glass, preferably of less than 0.8 J/m², or even 0.4 J/m² or less. Thus, the material may for example be a metal, used by itself or as an alloy, such as silver (with an adhesion energy of 0.35 J/m²), gold or tin, or more widely for example an inorganic material such as AgCl or MgF₂.

Consequently, the process makes it possible to obtain, in a simple and reproducible manner and on an industrial scale over large areas, a textured surface of the glass by easy operating steps for obtaining the mask and by adjusting the surface profile of the external surface in order to provide a profile perfectly suited to using the substrate in an OLED.

It is preferred to choose a low-cost industrial glass, for example a silicate glass, by preference a soda-lime-silica glass. The refractive index of the glass is conventionally about 1.5. Known high-index glasses may also be chosen.

According to a first embodiment, the moderating step comprises a heat treatment of the substrate at a temperature between 0.8 T_{g} and 1.25 T_{g}, where T_{g} is the glass transition temperature of the substrate, preferably so that the height between the highest point and the lowest point of the surface heat treated over a measurement length equal to the distance between two tops of projections separated from each other by the adjacent depressions, or over a measurement length equal to the distance between two bottoms of depressions separated from each other by the adjacent projections, is equal to or greater than 20 nm, preferably equal to or greater than 30 nm or even equal to or greater than 80 nm.

Thus, the temperature may typically be between 600 and 700° C., especially for soda-lime-silica glasses.

It is thus necessary to moderate sufficiently so as to avoid any electrical degradation, while maintaining a certain texturing of the surface in order to guarantee extraction. The reason for this is that the external texturing (typically waviness) disturbs the modal energy distribution.

According to a second (alternative or additional) embodiment, the moderating step comprises (or consists of) the liquid deposition of a smoothing layer, preferably a sol-gel layer.

As regards the deposition processes, the following processes suitable for depositing a sol-gel layer may especially be mentioned:
spin coating;
dip coating; and
spray coating.

In a first configuration of this second embodiment (moderating step comprising liquid, preferably sol-gel, deposition of a smoothing layer on the surface of the glass), the refractive index of the smoothing layer is substantially equal to that of the glass, for example with an index difference of less than 0.1, at 550 nm, for example a silica sol-gel layer. The deposition is preferably adapted so that the moderated external surface formed by the surface of the smoothing layer is such that the height between the highest point and the lowest point of the moderated external surface over a measurement length equal to the distance between two neighboring tops of projections separated from each other by the adjacent depressions or over a measurement length equal to the distance between two bottoms of neighboring depressions separated from each other by the adjacent projections, is equal to or greater than 30 nm, or even equal to or greater than 80 nm.

Again, it is thus necessary to moderate sufficiently so as to avoid any electrical degradation, while still maintaining a certain texturing of the surface in order to guarantee extraction.

For example:
the glass has an index of 1.5 and the smoothing layer is made of silica with an index of about 1.45, especially a sol-gel silica; or
the glass has an index of 1.7 or higher and the smoothing layer is made of TiO₂ or ZrO₂, especially a sol-gel layer.

In a second configuration of this second embodiment, the process comprises the liquid deposition of a smoothing layer (preferably a sol-gel layer) on the surface of the glass, the refractive index of which is greater than that of the glass of the substrate by at least 0.2, and preferably is between 1.7 and 2, especially equal to or less than the average index of the first electrode.

The level of texturing is less restricting and extraction is improved by virtue of the index difference between the glass (preferably soda-lime-silica glass with an index of 1.5) and the high-index smoothing layer and improved by the texturing of the glass. Increasing the smoothing layer texturing enhances extraction.

A refractive index greater than that of the glass for the smoothing layer makes it possible, when the substrate is used in an OLED in which both the organic layer and the first electrode have a refractive index higher than that of the glass, to cause less reflection of the light reaching the glass substrate and, on the other hand, to promote continuity of the light path through the substrate.

A layer (especially a sol-gel layer) made of TiO₂, ZrO₂, ZnO or SnO₂, particularly with a thickness of 50 to 500 nm and preferably 100 to 200 nm, may for example be chosen.

The first electrode generally has an average index of about 1.7 or even higher (1.8 or even 1.9). The difference between the average index of the first electrode and the index of the glass may be greater than 0.2, preferably greater than 0.4, in order to increase extraction.

Preferably, the difference between the index of the smoothing layer and the average index of the first electrode is as low as possible, for example 0.1 or less.

In a first configuration, the mask is obtained by depositing a layer of material having no affinity with the glass on that surface of the substrate to be etched and then by causing dewetting of the layer by heating it, in order to form the nodules that then constitute the etching mask, after which the etching mask is removed.

Preferably, the material of the mask is chosen from those having an etching rate that is different, preferably less than that of the glass under the chosen etching conditions (or even zero). If the etching rate of the material of the mask is greater than that of the glass, it is then necessary to choose a mask thickness such that mask material remains right to the end of the etching of the glass.

In a second configuration, the method of obtaining the mask on the surface of the substrate comprises:
dissociation of a solution within a flame and at atmospheric pressure, the solution comprising at least one precursor of the material having no affinity with the glass;
a step in which said flame is directed onto said surface in order to form the multitude of nodules based on said material having no affinity with the glass that constitute the etching mask; and
removal of the etching mask.

In a third configuration, such nodules forming this time a negative of the mask may be produced.

The second configuration is then produced in order to obtain the nodules, next a thin transparent etching-resistant dielectric coating is deposited between and on the nodules obtained, after which the nodules (forming the negative of the mask) that are covered with the thin coating are removed so as to form the mask from the thin dielectric coating left.

The mask may be preserved in this configuration and therefore the textured surface of glass and mask is moderated.

The term “transparent coating” is understood to mean a coating such that the light transmission of the substrate and of this mask left over is equal to or greater than 70% and even more preferably equal to or greater than 80%.

Preferably, this mask is thin, especially with a thickness of 10 nm or less. It may be a TiO₂, SnO₂, ZnO or SnₓZn_{y}O layer where x and y are between 0.2 and 0.8 and preferably with a thickness of 10 nm or less.

According to one feature of the process, the etching is dry etching, in particular reactive ion etching in a plasma gas of the SF₆ type.

As a variant, especially in the case of the dielectric mask, the etching is wet etching by that surface of the substrate to be etched being in contact with a wet solution, of the bath or liquid spray type.

After the etching, the Ag nodules remaining on the projections are removed by cleaning the surface of the substrate, for example using a liquid. It is also conceivable to remove them mechanically, especially by brushing.

Typically, the glass textured by dewetting may have projections in the form of cylindrical studs.

The invention also relates to a structure having a textured external surface that can be obtained by the above manufacturing process of the invention, comprising a substrate made of a mineral glass, the surface of which is provided with projections and depressions of submicron height and width in a random arrangement, the external surface of the structure being provided with projections and depressions of submicron height and width that are randomly arranged and have rounded angles.

The external surface may preferably be defined by a roughness parameter R_{dq} of less than 1.5° and a roughness parameter Rₘₐₓ of 100 nm or less over a 5 μm by 5 μm scanning area.

According to one feature, the surface of the glass comprises depressions separated from one another by adjacent projections, the tops of the projections being coated with a transparent dielectric material.

Preferably, the smoothing layer:
is dielectric (meaning nonmetallic), preferably electrically insulating (in general having an electrical resistivity in the bulk state, as known in the literature, of greater than 10⁹ Ω·cm) or semiconducting (in general with an electrical resistivity in the bulk state, as known in the literature, of greater than 10⁻³ Ω·cm but less than 10⁹ Ω·cm); and/or does not appreciably impair the transparency of the substrate—for example the substrate coated with the smoothing layer may have a light transmission T_{L} equal to or greater than 70% or even equal to or greater than 80%.

According to another feature, preferably the smoothing layer forming said external surface of the substrate is essentially a mineral and/or sol-gel layer.

A mineral smoothing layer rather than an organic layer of the polymer type may be made more easily thin and/or be temperature-resistant (therefore satisfying the constraints of certain OLED fabrication processes) and/or sufficiently transparent.

The smoothing layer, especially a sol-gel smoothing layer, is made of a TiO₂, ZrO₂, ZnO, SnO₂ or SiO₂ oxide.

The TiO₂ smoothing layer may have a thickness of 50 to 500 nm, preferably 100 to 200 nm.

The thickness is not necessarily identical at the tops and at the bottoms.

The surface of the glass may comprise projections separated from one another by adjacent depressions, the projections preferably having rounded angles so that the surface of the glass forms said external surface, the distance between two separated neighboring projections being between 150 nm and 1 μm and in particular between 300 nm and 750 nm, the range corresponding to visible light.

Likewise, the surface of the glass substrate may (as an alternative) have depressions separated from one another by adjacent projections, the projections preferably having rounded angles so that the surface of the glass forms said external surface, the distance between two bottoms of neighboring depressions being between 150 nm and 1 μm and in particular between 300 nm and 750 nm.

Preferably, most, indeed at least 80%, of the measured distances between two tops (or alternatively between two depressions) on the external surface or on the surface of the glass before heat treatment are between 150 nm and 1 μm, and in particular between 300 nm and 750 nm.

Preferably, the maximum distance between two tops (or alternatively between two depressions) on the external surface or on the surface of the glass before heat treatment is of the order of the longest wavelength emitted by the OLED.

Preferably, most, indeed at least 80%, of the external surface, especially the surface of the heat-treated glass, of the heights between the highest point and the lowest point of the surface over a measurement length equal to the distance between two tops of neighboring projections separated from each other or between two bottoms of neighboring depressions separated from each other is equal to or greater than 30 nm, or even equal to or greater than 80 nm.

Preferably, the smoothing layer, especially a sol-gel layer, is made of silica and over most, or indeed at least 80%, of the surface, the height between the highest point and the lowest point on the external surface of the smoothing layer (which may be heat-treated) over a measurement length equal to the distance between two tops of neighboring projections separated from each other or between two bottoms of neighboring depressions separated from each other is equal to or greater than 30 nm, or even equal to or greater than 80 nm.

The thicker the dewetting layer, the further apart the studs. Before heat treatment of the glass (or beneath the smoothing layer), the ratio of the width of the isolated projections (or isolated depressions) to the distance between two isolated projections (or isolated depressions) may be between 0.3 and 0.7 and even more preferably between 0.4 and 0.6.

The difference between the minimum width and the maximum width of a stud (before heat treatment of the glass or beneath the smoothing layer) may be equal to or greater than 300 nm or even equal to or greater than 500 nm.

The height of isolated projections (or isolated depressions) may be between 50 and 150 nm before heat treatment of the glass or beneath the smoothing layer. For example, before heat treatment of the glass or beneath the smoothing layer, most of the heights of the isolated projections (or isolated depressions) may be between 90 and 150 nm.

Likewise, most of the heights of coated isolated projections (or isolated depressions) on the external surface may be equal to or greater than 80 nm.

Moreover, the amplitude on the external surface may be predominantly equal to or greater than 80 nm.

Advantageously, the structure includes a thin-film electrode having a surface conformal to the external textured surface.

This first electrode, in the form of one or more deposited thin films, may be substantially conformal to the moderating subjacent external surface. These films are for example deposited by vapor deposition, especially by magnetron sputtering or by evaporation.

As already seen, the first electrode generally has an average index of about 1.7 or even higher (1.8 or even 1.9). The organic layer(s) then deposited on the electrode generally have an average index of around 1.8, or even higher (1.9 or even higher).

The final subject of the invention is an organic light-emitting diode (OLED) device incorporating the structure defined above, the textured external surface of the substrate being placed on the side with the organic light-emitting layer(s) (OLED system), i.e. on the inside of the device, the structure having a textured external surface being beneath a first electrode subjacent to the organic light-emitting layer(s).

The OLED may form an illumination panel or backlighting panel (providing substantially white and/or uniform light) especially having a full electrode area or equal to 1×1 cm² or even up to 5×5 cm², or even 10×10 cm² and greater.

Thus, the OLED may be designed to form a single illuminating tile (with a single electrode area) generating polychromatic (substantially white) light or a multitude of illuminating tiles (with several electrode areas) generating polychromatic (substantially white) light, each illuminating tile provided with a full electrode area greater than or equal to 1×1 cm², or even 5×5 cm², 10×10 cm² and greater.

Thus, in an OLED according to the invention, especially for illumination, a non-pixelated electrode may be chosen. This differs from an electrode for a display (LCD, etc.) screen formed from three juxtaposed pixels, generally of very small size, each emitting a given quasi-monochromatic radiation (typically red, green or blue).

The OLED system may be designed to emit polychromatic radiation defined at 0° by coordinates (x1, y1) in the CIE xyz (1931) colorimetric diagram, these coordinates therefore being given for radiation to the normal.

The OLED may further include a top electrode above said OLED system.

The OLED may be bottom-emitting and possibly also top-emitting, depending on whether the top electrode is reflecting or alternatively semi-reflecting, or even transparent (especially with a comparable T_{L} at the anode, typically upward of 60% and preferably equal to 80% or higher).

The OLED system may be adapted for emitting substantially white light, as close as possible to the (0.33; 0.33) coordinates or the (0.45; 0.41) coordinates, especially at 0°.

To produce substantially white light, several methods are possible: mixing of compounds (emitting in the red, green and blue) in a single layer; stacking, on the face of the electrodes, of three organic structures (emitting in the red, green and blue) or of two organic (yellow and blue) structures.

The OLED may be adapted so as to produce as output substantially white light as close as possible to the coordinates (0.33; 0.33) or the coordinates (0.45; 0.41), especially at 0°.

The device may form part of multiple glazing, especially vacuum glazing or glazing with a layer of air or another gas. The device may also be monolithic, comprising monolithic glazing in order to increase compactness and/or lightness.

The OLED may be bonded or preferably laminated to another flat substrate, called a cover, preferably transparent, such as a glass substrate, using a lamination interlayer, especially an extra-clear interlayer.

The invention also relates to the various applications which may be found for these OLEDs, forming one or more transparent and/or reflective (mirror function) luminous surfaces placed outdoors and indoors.

The device may form (alternative or additional choice) an illuminating, decorative, architectural or other system or an indicating display panel—for example of the design, logo or alpha-numeric type, especially an emergency exit panel.

The OLED may be arranged to produce uniform polychromatic light, especially for homogenous illumination, or to produce various luminous areas, having the same brightness or different brightness.

When the electrodes and the organic structure of the OLED are chosen to be transparent, an illuminating window may especially be produced. The illumination of a room can then be improved, but not to the detriment of light transmission. Furthermore, by limiting the light reflection, especially on the external side of the illuminating window, this also makes it possible to control the level of reflection for example in order to meet the antidazzling standards in force for the walls of buildings.

More broadly, the device, especially one that is partly or entirely transparent, may be:
intended for a building, such as an external luminous glazing panel, an internal luminous partition or a luminous glazed door (or part thereof), especially a sliding door;
intended for a transport vehicle, such as a luminous roof, a luminous side window (or part thereof), or a luminous internal partition of a vehicle traveling on land, on water or in the air (automobile, truck, train, aircraft, boat, etc.);
intended for urban or professional furniture, such as a bus shelter panel, a wall of a display cabinet, a jewelry display or a shop window, a wall of a glasshouse, an illuminating tile;
intended for internal furnishings, such as a shelf or furniture element, a front panel of an item of furniture, an illuminating tile, a ceiling, an illuminating refrigerator shelf, an aquarium wall;
intended for backlighting electronic equipment, especially a display screen, possibly a double screen, such as a television or computer screen, a tactile screen.

OLEDs are generally divided into two broad families depending on the organic material used.

If the light-emitting layers consist of small molecules, the OLEDs are referred to as SM-OLEDs (small-molecule organic light-emitting diodes). In general, the structure of an SM-OLED consists of a stack comprising a hole injection layer (HIL), a hole transport layer (HTL), an emissive layer and an electron transport layer (ETL).

Examples of organic light-emitting multilayer stacks are for example described in the document entitled “Four wavelength white organic light-emitting diodes using 4,4′-bis-[carbazoyl-(9)]-stilbene as a deep-blue emissive layer” by C. H. Jeong et al. published in Organic Electronics 8, pages 683-689, (2007).

If the organic light-emitting layers consist of polymers, the devices are referred to as PLEDs (polymer light-emitting diodes).

The present invention will now be described using examples, which are merely illustrative and in no way limit the scope of the invention, together with the appended illustrations in which:

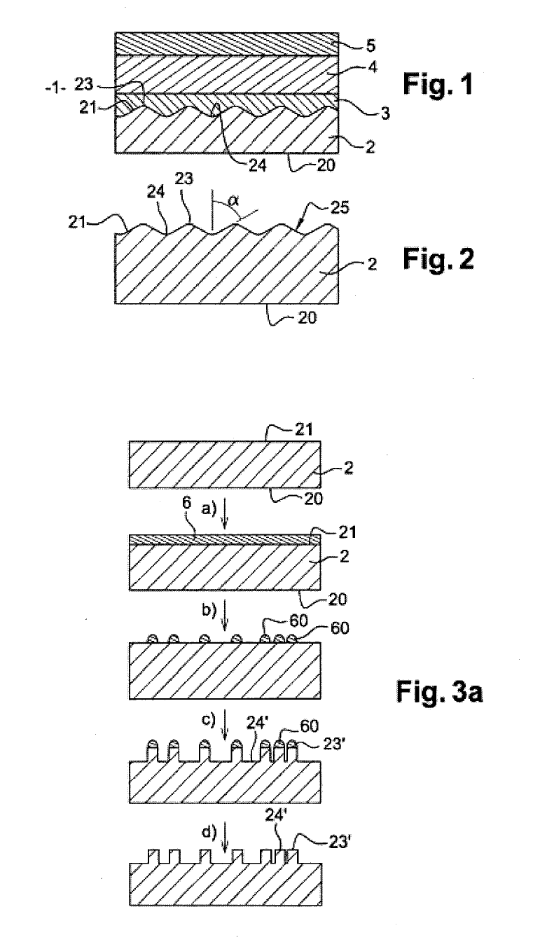

FIG. 1 is a schematic cross-sectional view of an OLED comprising a substrate according to the invention;

FIG. 2 is a cross-sectional view of the substrate of the invention;

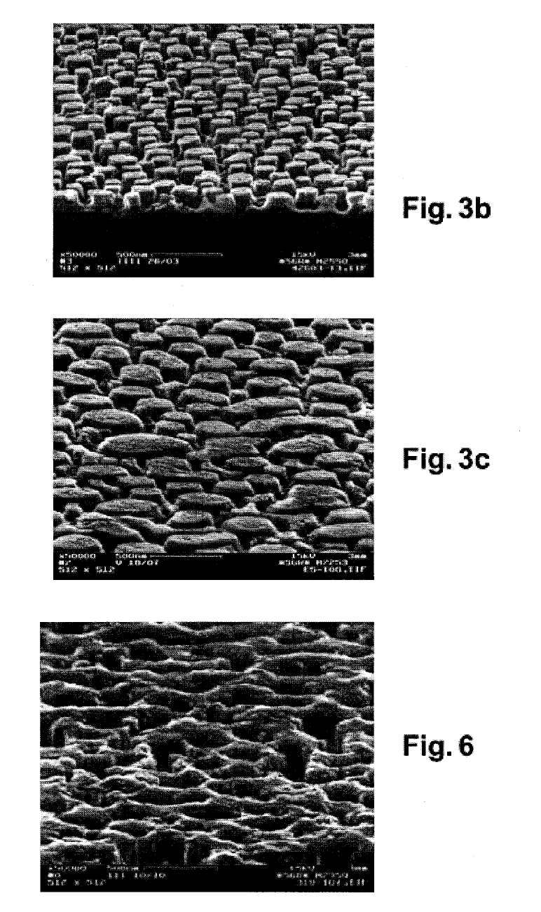

FIG. 3a shows the masking and etching steps of the process of the invention according to a first embodiment;

FIGS. 3b and 3c show SEM micrographs of the textured surface of the glass;

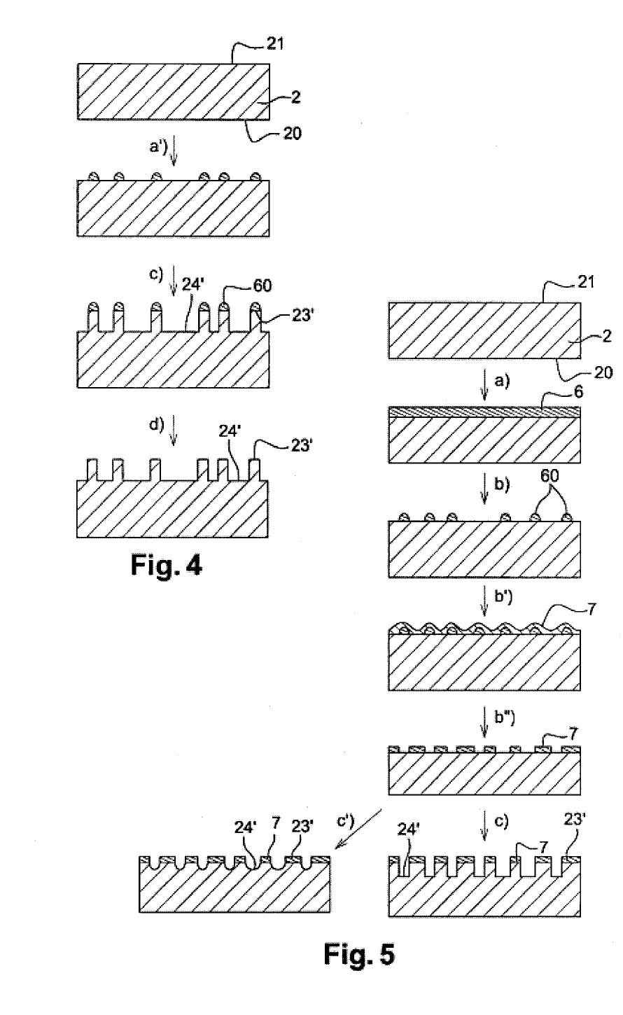

FIG. 4 shows the steps of the masking and etching process of the invention according to a second embodiment;

FIG. 5 shows the first steps of the process according to two additional embodiments;

FIG. 6 shows an SEM micrograph of the surface of the glass, textured by certain steps of FIG. 5;

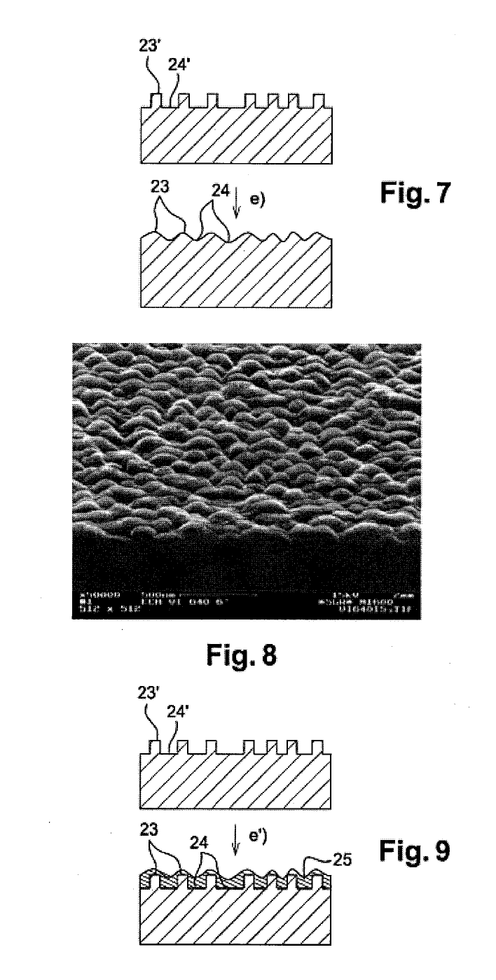

FIG. 7 shows an example of a step in which the etched substrate is moderated by heat treatment;

FIG. 8 shows an SEM micrograph of the textured surface of the glass flattened by heat treatment; and

FIG. 9 shows an example of a step in which the etched substrate is moderated by film deposition.

FIG. 1 illustrates an organic light-emitting device 1 that comprises, as is known, in succession, a mineral glass substrate 2, a transparent first electrode 3, a stack 4 of organic light-emitting layers and a second electrode 5.

The glass substrate 2 serves as support for the other elements of the OLED. It is made of soda-lime-silica glass, possibly clear or extra-clear, having for example a thickness of 2.1 mm. The substrate has a first face 20, which faces the outside and forms the surface for extracting light from the device, and a second, opposed face 21 on which the first electrode 3 is deposited (directly or otherwise).

The first electrode 3, or bottom electrode, comprises a transparent electroconductive coating such as one based on tin-doped indium oxide (ITO) or a silver multilayer.

The electrode multilayer comprises for example:
an optional base layer and/or wet-etching stop layer;
an optional sublayer, namely a layer of optionally doped mixed zinc tin oxide or a layer of mixed indium tin oxide (ITO) or a layer of mixed indium zinc oxide (IZO);
a contact layer based on a metal oxide, chosen from ZnOₓ, whether doped or not, Sn_{y}Zn_{z}Oₓ, ITO or IZO;
a metallic functional layer, for example a silver layer, having an intrinsic electrical conductivity property;
an optional thin overblocker layer directly on the functional layer, the thin blocker layer comprising a metal layer having a thickness of 5 nm or less and/or a layer having a thickness of 10 nm or less, which is based on a substoichiometric metal oxide, a substoichiometric metal oxynitride or a substoichiometric metal nitride (and optionally a thin underblocker layer directly beneath the functional layer);
an optional protective layer chosen from ZnOₓ, Sn_{y}Zn_{z}Oₓ, ITO or IZO; and
an overlayer based on a work-function-matching metal oxide for said electrode coating.

The following may for example be chosen as electrode multilayer: Si₃N₄/ZnO:Al/Ag/Ti or NiCr/ZnO:Al/ITO, having respective thicknesses of 25 nm for the Si₃N₄, 5 to 20 nm for ZnO:Al, 5 to 15 nm for the silver, 0.5 to 2 nm for the Ti or NiCr, 5 to 20 nm for the ZnO:Al and 5 to 20 nm for the ITO.

Placed on the optional base layer and/or wet-etching stop layer and/or sublayer is the following structure repeated n times, where n is an integer equal to or greater than 1 (in particular n=2, i.e. a silver bilayer):
the contact layer;
optionally, the thin underblocker layer;
the functional layer;
the thin overblocker layer; and
optionally, the protective layer, for protection against water and/or oxygen.

The final layer of the electrode remains the overlayer.

Thus, mention may be made of a silver multilayer, for example as described in the documents WO 2008/029060 and WO 2008/059185.

The multilayer consisting of organic layers 4 comprises a central light-emitting layer inserted between an electron transport layer and a hole transport layer, these themselves being inserted between an electron injection layer and a hole injection layer.

The second electrode 5, or top electrode, is made of an electrically conductive and preferably (semi) reflective material, in particular a metallic material of the silver or aluminum type.

We will not describe in more detail the technical and functional aspects of each of the elements 4 and 5 of the device—as these aspects are known per se, they are not the subject matter of the present invention.

To ensure optimum light extraction, the substrate 2 of the OLED has, according to the invention (FIG. 2), a textured external surface intended to be in contact with the bottom electrode 3 and formed by an alternation of randomly distributed projections 23 and depressions 24.

The inventors have demonstrated that it is of paramount importance for the external surface (either the surface of the glass itself or of a smoothing layer of the textured glass) to be sufficiently moderated, typically with rounded angles.

Thus, the external surface is defined by a roughness parameter R_{dq} of less than 1.5° and a roughness parameter Rₘₐₓ of 100 nm or less over a 5 μm by 5 μm scanning area. The angles may be measured by means of an atomic force microscope.

In parallel, the angle α made by the tangent at a majority of the points of the pattern to the normal to the substrate may be equal to or greater than 30°, and preferably at least 45°. The angles may be measured by microscopy.

The textured external surface may also be defined by a roughness parameter Rₘₐₓ equal to or greater than 20 nm over a 5 μm by 5 μm scanning area, by AFM.

The process of the invention serves to obtain such a moderated external surface.

The texturing is firstly produced on the bare glass substrate, thus giving it randomly distributed projections 23′ and depressions 24′. The process consists in:
generating an etching mask on the surface 21 of the glass substrate;
etching the substrate around the mask (cf. FIGS. 3a, 4 and 5); and
to form the moderated external surface, either, according to a first embodiment of the invention (cf. FIG. 7), subjecting the etched substrate to a heat treatment or, according to a second embodiment (cf. FIG. 9), depositing a transparent smoothing layer on the surface of the etched substrate.

The two separate embodiments, differing as regards the moderating step, will be described later. Only the various different ways of obtaining the mask and for carrying out the etching are explained here.

FIG. 3a illustrates a first example of the process for obtaining the mask and for carrying out the etching.

In a first step a), a metallic material 6 such as silver, which is to form the mask, is deposited by covering the entire surface 21 of the substrate (or at least a predetermined area thereof).

In a second step b), the layer is dewetted by heating in an oven at a temperature between 200 and 400° C. in order to obtain randomly distributed metal nodules 60.

In step c) the substrate is etched, advantageously by plasma-enhanced dry etching. This etching technique consists in placing two electrodes, one facing the Ag nodules and the other facing the opposite face 20 of the glass substrate, in an atmosphere at low pressure, typically between 50 mTorr and 1 Torr, of a plasma gas such as SF₆.

This results in an alternation of projections 23′ and cavities or depressions 24′ between the Ag nodules 60 of the mask, the nodules lying on top of the projections.

After the etching operation, the Ag nodules remaining on the projections are removed by cleaning the surface of the substrate (step d)), for example by immersing the etched substrate in an aqueous acid solution, such as an HNO₃ solution. It is also conceivable to remove them mechanically, especially by brushing.

FIG. 3b shows a scanning electron microscope view at an angle of 15° with a magnification of 50,000 of the textured surface of a substrate produced according to the technique shown in FIG. 3a and by means of dry etching.

The surface of such a textured glass forms a plurality of projections in the form of studs of polygonal (more or less cylindrical) cross section and of variable width.

The thickness of the Ag mask is 10 nm. The dewetting temperature is 300° C. and the dewetting time is 10 minutes.

The etching time is 15 minutes in an SF₆ plasma with a flow rate D_{SF6}=500 sccm at a pressure P=80 mTorr using a low-frequency cathode (to ignite the plasma) operating at 100 kHz and 75 W, and an RF power of 35 W (to direct the plasma).

The etching obtained is anisotropic etching. The distance between two tops of neighboring projections (studs) is predominantly around 300 nm±150 nm and the height of the studs is between 80 and 100 nm.

FIG. 3c shows a scanning electron microscope view at an angle of 15° with a magnification of 50,000 of the textured surface of a glass produced according to the technique shown in FIG. 3 and by means of dry etching.

The thickness of the Ag mask is 20 nm. The dewetting temperature is 300° C. and the dewetting time is 15 minutes.

The etching time is 15 minutes, in an SF₆ plasma, with a flow rate D_{SF6}=500 sccm at a pressure P=80 mTorr using a low-frequency cathode (to ignite the plasma) operating at 100 kHz and 75 W and an RF supply of 35 W (to direct the plasma).

The etching obtained is anisotropic etching. The distance between two tops of neighboring projections (studs) is predominantly around 600 nm±300 nm and the height of the studs is about 100 nm.

FIG. 4 shows the steps of the masking and etching process of the invention according to a second embodiment. The etching and cleaning steps c) and d) are identical to those of the example shown in FIG. 3a, only steps a) and b) for obtaining the mask are different.

In this embodiment, the Ag nodules forming the mask are obtained directly using a combustion CVD technique (step a′). This involves spraying, onto the surface 21 of the substrate, in the form of droplets and at atmospheric pressure, a solution comprising at least one precursor of a material that will constitute the mask, while at the same time directing a flame onto said surface so that the material separates from the solution and is randomly deposited in the form of a plurality of nodules 60. The discrete mask of nodules resulting from the dissociation of the precursor of the material within the flame may have several zones with different patterns, differing by their size (both width and height) and/or their orientation and/or their distance.

To give an example, the solution is an aqueous solution of silver nitrate with a concentration of 0.5 mol/l. The nebulizing N₂ flow rate is 1.7 slm and the diluting N₂ flow rate is 13.6 slm. The distance from the flame to the substrate is about 10 mm with relative movement between the flame and the substrate, such as to perform around 10 passes. The temperature of the substrate exposed to the flame is about 80° C.

The nodules 60 obtained are of nanoscale size with distances between two tops that are those expected for the intended application of the invention.

Of course, the production parameters (substrate temperature, substrate/flame distance, pass speed, precursor concentration) are adjusted according to the aspect ratio of the desired patterns and the desired density of the patterns.

FIG. 5 shows the masking and etching steps of the process according to two additional embodiments.

This alternative process repeats steps a) and b) of the embodiment shown in FIG. 3a (or step a′) of FIG. 4) and carries out the following additional steps before the etching operation:
a thin film 7 of transparent dielectric material, for example TiO₂, is deposited with a thickness of 2 to 20 nm on the substrate provided with the Ag nodules (step b′) by vacuum magnetron sputtering, forming a negative of the etching mask; and
the silver is removed by mechanical rubbing or by a solution in an acid bath, in the same way as described in step d) of FIGS. 3a and 4. Removal of the silver, which does not have the properties of bonding with the glass, also leads to the thin film 7 of TiO₂ that covers the nodules being locally removed. This step, referenced b″) in FIG. 5, results in a randomly patterned TiO₂ etching mask on the surface of the substrate.

Once the etching mask has been obtained, the next step of the process, which consists of the etching operation, may advantageously be carried out, for a substrate obtained with such a mask, either by dry etching (step c in FIGS. 3a and 4) or by wet etching (step c′).

The wet etching (step c′) consists in applying, for example, a hydrofluoric acid solution, either by immersion in a bath or by spraying. This etching step produces isotropic cavities of spherical type (the walls of the depressions being vertical or perpendicular to the plane of the glass), contrary to dry etching which forms anisotropic cavities (walls curved in all directions).

FIG. 6 shows a scanning electron microscope view at a magnification of 50,000 of a textured glass produced using the technique of FIG. 5 and by means of dry etching.

The distance between two neighboring depressions is predominantly around 400 nm±200 nm.

The production conditions are as follows:
deposition of a silver layer with a thickness of between 10 and 15 nm by magnetron sputtering using a DC supply;
dewetting of this layer by heating in the atmosphere at 300° C. for 15 minutes;
deposition of a 10 nm layer of TiO₂ by magnetron sputtering using a TiOₓ ceramic target with a pulsed supply of 2 kW, a pressure of 2.5 μbar, an Ar/O₂ mixture and a run speed of 10 cm/min;
removal of the Ag nodules and the TiO₂ that covers them, by cleaning the surface with 0.1M nitric acid (HNO₃) for 8 hours; and
etching the glass using an SF₆ plasma: low-frequency cathode operating at 100 kHz and 75 W; RF biasing the substrate with 35 W; P=80 mTorr; D_{SF6}=500 sccm (the same conditions as in the case of the studs).

After etching, since the material of the mask is TiO₂, and therefore a transparent dielectric material, there is really no necessity to remove it.

The etched substrates have nanotexturing features which however do not meet the desired characteristics to form an OLED support substrate, in particular as regards the slope that the projections have relative to the plane of the substrate, which slope must not be too acute.

The invention provides, in addition to the steps described above for forming a textured external surface, an additional step that consists, as already indicated briefly, according to a first embodiment, in carrying out a heat treatment on the textured glass (FIG. 7) forming moderated projections 23 and depressions 24 or, according to a second embodiment, in depositing by liquid processing a transparent smoothing layer 25 which may or may not differ in refractive index from that of the glass, but is preferably greater, forming moderated projections 23 and depressions 24 (FIG. 9).

The first embodiment using heat treatment consists in heating (step e) the etched substrate in a furnace at a temperature between 600 and 700° C. for a time of between 2 and 30 minutes. The softening of the substrate results in moderation of the textured surface, by moderating the slopes of the projections. The duration of the heat treatment depends on the desired angle between the tangent at any point on a projection and the normal to the substrate, said angle being equal to or greater than 30°.

FIG. 8 shows a scanning electron microscope view at a magnification of 50,000 of the textured and heat-treated surface (the initial surface finish before annealing being similar to that shown in FIG. 3b). Appreciable moderation of the studs is observed.

A second embodiment consists in depositing the thin layer 25 by liquid processing (step e′ of FIG. 9). This liquid method makes it possible to deposit a thickness which is always somewhat greater in the bottom of the cavities than on top of the projections, modeling the slopes in accordance with the desired expectation. In contrast, a physical deposition process would not be appropriate as it would follow the profile of the substrate perfectly and would thus in no way modify the slope of the projections.

It will be recalled that the process for forming a sol-gel layer has the advantage of being carried out at room temperature. The starting point may be a homogeneous solution of molecular precursors, which are converted into solid form by an inorganic polymerization chemical reaction at room temperature. The solution of precursors polymerized to a greater or lesser extent is called a sol and this is converted into a gel upon being aged.

To moderate a surface having a relief, the most important parameter is the thickness of the layer that serves for the moderation. For a given deposition process, this thickness is directly dependent on the solids content of the formulation. The solids content is defined as the % by weight of material in the initial formulation that is found in the layer after deposition. In the case of formulations containing alkoxides of formula M(OR)ₙ, the total alkoxide mass is not taken into account, rather it is the equivalent oxide mass, since an alkoxide hydrolyzes to M(OH)ₙ and then condenses to MOₓ, releasing the alcohol ROH.

For example, for a silica layer produced from Si(OEt)₄, the equivalent mass of SiO₂ is taken (replaced mole for mole). The moderating operation has to be carried out while still maintaining corrugations sufficient for the intended purpose, i.e. preferably a minimum to maximum height difference equal to or greater than 50 nm, or even 80 nm, over the distance between two tops of neighboring coated studs.

For example in the case of a structure consisting of studs about 100-200 nm in height occupying 50% of the surface, a layer of silica giving 40 nm as full face is chosen in order to fill the holes with at least 80 nm of silica, hence a solids content of about 1.5%.

The initial composition is based on a silicon alkoxide, namely tetraethoxysilane (TEOS, of formula Si(OC₂H₅)₄) used in water acidified with hydrochloric acid in order to obtain a pH of 2.5.

The preparation of the composition for the smoothing layer consists in:
adding 1 g of TEOS to 19 g of deionized water acidified with HCl (the pH of the water being equal to 2.5); and
stirring the mixture for two hours at room temperature.

The sol obtained has a solids content of 1.5%.

Other compositions are possible:

| | | Mass of |
|---|---|---|
| | Mass of TEOS | acidified water |
| Solids content | (g) | (g) |
| 1% | 0.7 | 19.3 |
| 2% | 1.4 | 18.6 |
| 2.5% | 1.7 | 18.3 |

After reaction, the various mixtures are deposited by spin coating at 1000 rpm on the structured glass and then dried for 30 minutes at 120° C.

For the TiO₂ layers produced from Ti(OBu)₄ and acetylacetone, which serves as complexing agent, the equivalent mass of TiO₂ and the mass of acetylacetone, which remains in the layer if the heat treatment is not carried out at high temperature, are taken.

For example, a layer of TiO₂ is deposited with a thickness of 200 nm or even more. This layer may be thicker than the depth of etching.

For example, the smoothing layer is based on an alkoxide of formula M(OR)ₙ, in particular a titanium alkoxide, a complexing agent, acetylacetone and a solvent, namely isopropanol.

The preparation of the composition for the smoothing layer consists in:
adding 0.5 ml of acetylacetone to 4.7 mL of isopropanol;
slowing adding 1.65 mL of titanium butoxide with stirring;
stirring the mixture for two hours at room temperature; and
diluting the mixture with 0.88 mL isopropanol.

This mixture has a solids content of 8%.

After reaction, the mixture is deposited by spin coating at 1000 rpm onto the structured glass and then dried for 30 minutes at 80° C.

1. A process for obtaining a structure having a textured external surface for an organic light-emitting device, which structure includes a mineral glass substrate having a surface which is provided with projections and depressions the process comprising:
depositing an etching mask on a surface of the substrate;
etching the surface of the substrate around the etching mask, and optionally removing the mask, wherein depositing the etching mask includes forming a multitude of nodules randomly arranged on the surface of the substrate and made of a material possessing no affinity with the glass and wherein, after said etching, the process includes moderating the structure so that slopes of the projections of submicron height and width obtained by etching are moderated sufficiently to form a moderated textured external surface.

2. The process as claimed in claim 1, wherein said moderating is such that the external surface is defined by a roughness parameter R_{dq} of less than 1.5° and a roughness parameter Rₘₐₓ of 100 nm or less over a 5 μm by 5 μm scanning area.

3. The process as claimed in claim 1, wherein said moderating comprises heat treating the substrate at a temperature between 0.8 T_{g} and 1.25 T_{g}, where T_{g} is the glass transition temperature of the substrate, so that a height between the highest point and the lowest point of the external surface heat treated over a measurement length equal to a distance between two tops of projections separated from each other by the adjacent depressions, or over a measurement length equal to a distance between two bottoms of depressions separated from each other by the adjacent projections, is equal to or greater than 20 nm.

4. The process as claimed in claim 1, wherein said moderating comprises performing a liquid deposition of a smoothing layer on the surface of the substrate, preferably a sol-gel layer, the refractive index of which is substantially equal to that of the glass, said deposition being adapted so that a height between the highest point and the lowest point of the moderated external surface, formed by the smoothing layer, over a measurement length equal to a distance between two neighboring tops of projections separated from each other by the adjacent depressions or over a measurement length equal to a distance between two bottoms of neighboring depressions separated from each other by the adjacent projections, is equal to or greater than 30 nm.

5. The process as claimed in claim 1, wherein said moderating comprises performing a liquid deposition of a smoothing layer on the surface of the glass, preferably a sol-gel layer, the refractive index of which is greater than that of the glass of the substrate by at least 0.2 and preferably is between 1.7 and 2.

6. The process as claimed in claim 1, wherein the material having no affinity with the glass has an energy of adhesion to the glass of less than 0.8 J/m² and is preferably a metallic material.

7. The process as claimed in claim 1, wherein depositing the etching mask comprises:
depositing a layer of said material having no affinity with the glass on that surface of the substrate to be etched;
dewetting said layer by heating, so as to form the nodules that constitute the etching mask; and
removing the etching mask.

8. The process as claimed in claim 1, wherein depositing the etching mask on the surface of the substrate comprises:
dissociating a solution within a flame and at atmospheric pressure, the solution comprising at least one precursor of said material having no affinity with the glass;
directing said flame onto said surface in order to form the multitude of nodules based on said material having no affinity with the glass that constitute the etching mask; and
removing of the etching mask.

9. The process as claimed in claim 1, wherein depositing the etching mask comprises:
depositing a layer of said material having no affinity with the glass on that surface of the substrate to be etched, or dissociating a solution within a flame and at atmospheric pressure, the solution comprising at least one precursor of said material not having any affinity with the glass;
dewetting of said layer by heating to form the nodules that form a negative of the etching mask;
depositing a thin transparent etching-resistant dielectric coating on and between the nodules; and
removing the nodules covered with the thin dielectric coating to form the mask from the thin dielectric coating left.

10. The process as claimed in claim 1, wherein the etching is a dry etching, in particular reactive ion etching in a plasma gas of the SF₆ type.

11. The process as claimed in claim 1, wherein the etching is a wet etching by that surface of the substrate to be etched being in contact with a wet solution, of a bath or liquid spray type.

12. A structure having a textured external surface that is obtainable by the manufacturing process as claimed in claim 1, comprising:
a substrate made of a mineral glass, a surface of which is provided with projections and depressions of submicron height and width in a random arrangement, an external surface of the structure being provided with projections and depressions of submicron height and width that are randomly arranged and have rounded angles.

13. The structure having an external textured surface as claimed in claim 12, wherein the external surface is defined by a roughness parameter R_{dq} of less than 1.5° and a roughness parameter Rₘₐₓ of 100 nm or less over a 5 μm by 5 μm scanning area.

14. The structure having an external textured surface as claimed in claim 12, wherein the surface of the glass comprises depressions separated from one another by adjacent projections, the tops of the projections being coated with a transparent dielectric material.

15. The structure having an external textured surface as claimed in claim 14, wherein the surface of the substrate has depressions separated from one another by adjacent projections, the projections having rounded angles so that the surface of the glass forms said external surface, the distance between two bottoms of neighboring depressions being between 150 nm and 1 μm and in particular between 300 nm and 750 nm.

16. The structure having an external textured surface as claimed in claim 12, wherein the surface of the glass comprises projections separated from one another by adjacent depressions, the projections having rounded angles so that the surface of the glass forms said external surface, the distance between two separated neighboring projections being between 150 nm and 1 μm and in particular between 300 nm and 750 nm.

17. The structure having an external textured surface as claimed in claim 16, wherein the textured surface of the glass is coated with a smoothing layer, preferably an essentially mineral and/or sol-gel layer, forming said external surface.

18. The structure having an external textured surface as claimed in claim 17, wherein the smoothing layer, especially a sol-gel smoothing layer, is made of silica, and a height between the highest point and the lowest point of the external surface of the smoothing layer which is heat treated, over a measurement length equal to a distance between two tops of neighboring projections separated from each other or between two bottoms of neighboring depressions separated from each other is equal to or greater than 30 nm.

19. The structure having an external textured surface as claimed in claim 12, wherein the smoothing layer, especially a sol-gel smoothing layer, is made of a TiO₂, ZrO₂, ZnO or SnO₂ oxide.

20. The structure having an external textured surface as claimed in claim 12, comprising a thin-film electrode having a surface conformal to the external surface.

21. An organic light-emitting diode device comprising a structure obtained by the process as claimed in claim 1, the textured external surface of the substrate being placed on a side with organic light-emitting layer(s), the structure having a textured external surface beneath a first electrode subjacent to the organic light-emitting layer(s).

22. An organic light-emitting diode device comprising a structure as claimed in claim 12, the textured external surface of the substrate being placed on a side with organic light-emitting layer(s), the structure having a textured external surface being beneath a first electrode subjacent to the organic light-emitting layer(s).
